(19) United States
(12) Patent Application Publication
(10) Pub. No.: US 2020/0063253 A1
(43) Pub. Date: Feb. 27, 2020

(54) CRUCIBLE

(71) Applicant: BOE Technology Group Co., Ltd., Beijing (CN)

(72) Inventors: Wei QUAN, Beijing (CN); Chang Yen WU, Beijing (CN)

(21) Appl. No.: 15/751,189

(22) PCT Filed: Jul. 27, 2017
(86) PCT No.: PCT/CN2017/094658

§ 371 Date: Feb. 8, 2018

(30) Foreign Application Priority Data
Jan. 24, 2017 (CN) 201720105076.X

(51) Int. Cl. C23C 14/24

(52) U.S. Cl. CPC C23C 14/243

(57) ABSTRACT

The disclosure provides a crucible. The crucible includes a crucible body, wherein the crucible body includes a first crucible component (11) and a second crucible component (12), and a volume of the second crucible component (12) is smaller than that of the first crucible component (11); and the first crucible component (11) includes an opening (111) and a bottom surface (112) facing the opening (111), an end of the second crucible component (12) is connected with the bottom surface of the first crucible component (11), and an internal cavity of the second crucible component (12) connects with an internal cavity of the first crucible component (11). The crucible can prevent evaporation material in the crucible with a large volume from being heated non-uniformly.

### RELATED APPLICATION

This application is a National Stage of International Application No. PCT/CN2017/094658, filed Jul. 27, 2017, which claims priority to Chinese Patent Application No. 201720105076.X, filed Jan. 24, 2017, both of which are hereby incorporated by reference in their entireties.

### TECHNICAL FIELD

This disclosure relates to a crucible.

### BACKGROUND

An OLED display device has advantages of self-luminescence, a simple structure, a light weight, a high response speed, a wide angle of view, a possibility of a flexible display, etc., and has been widely applied at present to a mobile phone, and other terminals. The OLED display device at present is generally fabricated through vacuum evaporation under such a principle that an evaporation material is heated to a certain temperature, and sublimed, and then deposited on a substrate through holes on a mask, thus resulting in a film of the OLED display device.

At present, the evaporation material is typically heated using a crucible, and in an evaporation process, the evaporation material is placed inside the crucible, and the crucible is heated using a heating device arranged outside of the crucible, so that the evaporation material in the crucible is heated. While the evaporation material is being heated, the outmost evaporation material is firstly heated, and then further conducts the heat to the inner evaporation material. And when the crucible is large, or there is a large amount of the evaporation material, the heat is conducted so slowly that the evaporation material tends to be heated non-uniformly, thus resulting in a risk of denaturing an overheated part of the evaporation material, and also easily incurring the problems of blocking holes of the crucible, and degrading the utilization ratio of the evaporation material.

### SUMMARY

At least one embodiment of the disclosure provides a crucible including a crucible body, wherein the crucible body includes a first crucible component and at least one second crucible component, and a volume of each of the at least one second crucible component is smaller than that of the first crucible component; and the first crucible component includes a first opening and a bottom surface facing the first opening, an end of each of the at least one second crucible component is connected with the bottom surface of the first crucible component, and an internal cavity of each of the at least one second crucible component connects with an internal cavity of the first crucible component.

In some examples, the crucible body includes a plurality of second crucible components.

In some examples, each of the at least one second crucible component includes a second opening, the bottom surface of the first crucible component includes a plurality of through-holes, and the second opening of each of the at least one second crucible component is connected with one of the plurality of through-holes, so that the internal cavity of each of the at least one second crucible component connects with the internal cavity of the first crucible component.

In some examples, the crucible further includes a heating device arranged outside of each of the at least one second crucible component.

In some examples, the heating device includes an electric heating sleeve arranged outside of each of the at least one second crucible component.

In some examples, the heating device includes electric heating wires arranged outside of each of the at least one second crucible component.

In some examples, the crucible further includes a refrigeration device arranged outside of each of the at least one second crucible component.

In some examples, the refrigeration device includes a cold medium pipe arranged outside of each of the at least one second crucible component.

In some examples, the plurality of second crucible components are spaced apart from each other on the bottom surface and the heating device is configured to encircle each of the plurality of second crucible components.

In some examples, an area of a section of the first crucible component in a direction parallel to the bottom surface increases gradually from the bottom surface of the first crucible component to the first opening.

In some examples, the first crucible component is structured as a circular truncated cone; a diameter of an end of the first crucible component where the first opening is located is larger than a diameter of an end of the first crucible component where the bottom surface is located.

In some examples, the crucible body further includes a cover covering the first opening of the first crucible component, and there are a plurality of evaporation holes arranged on the cover.

In some examples, the plurality of evaporation holes are arranged in an array on the cover.

### BRIEF DESCRIPTION OF THE DRAWINGS

In order to make the technical solutions in the embodiments of the disclosure more apparent, the drawings in the embodiments will be introduced below in brief, and apparently the drawings to be described below are merely illustrative of some embodiments of the disclosure, but not intended to limit the disclosure thereto.

FIG. 1 is a schematic structural diagram of a crucible body of a crucible according to an embodiment of the disclosure;

FIG. 2 is a schematic structural diagram of the crucible according to an embodiment of the disclosure in an exploded view; and

FIG. 3 is a schematic structural diagram of the crucible according to an embodiment of the disclosure in an assembled view.

### DETAILED DESCRIPTION OF THE EMBODIMENTS

In order to make the objects, technical solutions, and advantages of the embodiments of the disclosure more apparent, the technical solutions according to the embodiments of the disclosure will be described below clearly and fully with reference to the drawings in the embodiments of the disclosure, and apparently the described embodiments are only a part but all of the embodiments of the disclosure. Based upon the embodiments of the disclosure here, all of other embodiments derived by those ordinarily skilled in the art without any inventive effort shall come into the scope of the disclosure as claimed.

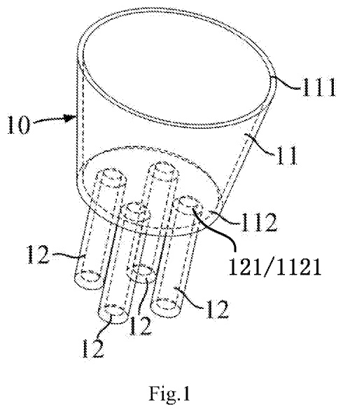

As illustrated in FIG. 1, embodiments of the disclosure provide a crucible including a crucible body 10. The crucible body 10 includes a first crucible component 11 and at least one second crucible component 12. For example, the first crucible component 11 illustrated in FIG. 1 is structured as a circular truncated cone, and each second crucible component 12 is structured as a cylinder. In some examples, both the first crucible component 11 and each second crucible component 12 can be structured as circular truncated cones or cylinders, and a volume of each second crucible component 12 is smaller than that of the first crucible component 11. When there is a smaller volume of each second crucible component 12, there is a smaller amount of evaporation material therein, so heat can be conducted therein quickly to thereby improve the rate of heating the evaporation material in the each second crucible component 12. In some examples, a volume of each second crucible component 12 can be set according to the amount of the evaporation material to be heated, and a heating rate as required. The first crucible component 11 and each second crucible component 12 will not be limited to the shape of the circular truncated cone or the cylinder, and for example, cross sections of the first crucible component 11 and each second crucible component 12 may be triangles, quadrilaterals, or polygons.

Since there is an insignificant difference in thickness between crucible walls of the first crucible component and each second crucible component, a volume relationship between the first crucible component and each second crucible component also reflects a capacity relationship between the first crucible component and the each second crucible component in some embodiments of the disclosure. For example, the volume of the first crucible component is larger than the volume of each second crucible component, and a capacity of the first crucible component is also larger than that of the each second crucible component.

The first crucible component 11 includes an opening 111, and a bottom surface 112 facing the opening 111, an end of each second crucible component 12 is connected with the bottom surface 112 of the first crucible component 111, and an internal cavity of each second crucible component 112 connects with an internal cavity of the first crucible component 11. In some examples, the first crucible component 11 can be connected with each second crucible component 112 through welding, casting, etc.

As illustrated in FIG. 1, for example, each second crucible component 12 includes a second opening 121, and there are a plurality of through-holes 1121 on the bottom surface 112 of the first crucible component 11, and a second opening 121 of each second crucible component 12 is connected with one of the plurality of through-holes 1121, so that the internal cavity of each second crucible component 12 connects with the internal cavity of the first crucible component 11.

The crucible according to some embodiments of the disclosure includes the crucible body 10, the crucible body 10 includes the first crucible component 11 and a plurality of the second crucible components 12, the volume of each of which is smaller than that of the first crucible component 11, and an end of each second crucible component 12 is arranged on the bottom surface 112 of the first crucible component 11, and the internal cavity thereof connects with the first crucible component 11. And in order to heat the evaporation material, the evaporation material is placed in the plurality of the second crucible components 12 respectively, and the respective parts of the evaporation material in the respective second crucible components 12 are heated concurrently. Since the evaporation material is divided into several parts, and the parts thereof are heated respectively, the heat can be conducted in the respective parts of the evaporation material at a higher rate than the rate at which the heat is conducted throughout the evaporation material as a whole, so that the respective parts of the evaporation material can be evenly heated in the inside and outside to thereby improve the problem of heating the evaporation material non-uniformly, so as to improve the problems of denaturing an overheated part of the evaporation material, and easily blocking the holes of the crucible, and degrading the utilization ratio of the evaporation material.

In order to heat the evaporation material in each second crucible component 12, the crucible according to some embodiments of the disclosure further includes a heating device arranged outside of each second crucible component 12.

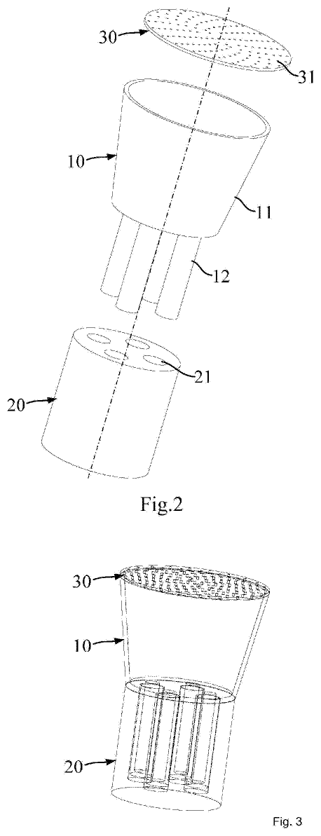

In order to facilitate the control of the temperature at which each second crucible component 12 is heated, and to improve the uniformity of heating each second crucible component 12, in some examples, the heating device includes an electric heating sleeve 20 arranged outside of each second crucible component 12 as illustrated in FIG. 2 and FIG. 3. For example, there are four accommodating holes 21 on the electric heating sleeve 20, and each accommodating hole 21 is arranged corresponding to one second crucible component 12, and is in sleeve joint with the corresponding second crucible component 12. The temperature of the electric heating sleeve 20 is controlled at high precision, and there is a large heating area thereof, so that the precision of controlling the temperature at which each second crucible component 12 is heated can be improved, and the uniformity of heating each second crucible component 12 can also be improved.

For example, as illustrated in FIG. 2 and FIG. 3, the plurality of the second crucible components are spaced apart from each other on the bottom surface and the electric heating sleeve is configured to encircle each of the plurality of the second crucible components.

Each second crucible components 12 can alternatively be heated using electric heating wires instead of the electric heating sleeve 20, so in some examples, the heating device includes electric heating wires arranged outside of each second crucible component 12. For example, the electric heating wires are arranged outside of each second crucible component in a similar pattern to the electric heating sleeve, so reference can be made to the structure illustrated in FIG. 2 and FIG. 3 for the pattern in which they are arranged.

After the evaporation material in the crucible body 10 is heated, in order to improve the rate of cooling the evaporation material, the crucible according to some embodiments of the disclosure further includes a refrigeration device arranged outside of each second crucible component 12, where the refrigeration device can improve the rate of cooling the evaporation material in each second crucible component 12 to thereby improve the efficiency of replacing the evaporation material, and maintaining the device.

For example, the refrigeration device can be embodied as a cold medium pipe, so in some examples, the refrigeration device includes a cold medium pipe enwound outside of each second crucible component 12, and the cold medium pipe can be embodied as a copper pipe in which refrigerant is injected, for example.

In order to increase an evaporation angle of the crucible, and to enable evaporation gas, into which the evaporation material is heated, to be mixed uniformly, an area of a section of the first crucible component 11 in a direction parallel to the bottom surface 112 increases gradually from the bottom surface 112 of the first crucible component 11 to the opening 111. In some examples, as illustrated in FIG. 1, the first crucible component 11 is structured as a circular truncated cone, and a diameter of an end of the first crucible component 11 where the opening 111 is located is larger than a diameter of an end of the first crucible component 11 where the bottom surface 112 is located. The first crucible component 11 structured as a circular truncated cone facilitates uniform mixing of the evaporation gas, improves the uniformity of the evaporation gas escaping from the crucible, and can increase the evaporation angle of the crucible, thus alleviating a shadow effect arising from a too small evaporation angle of the crucible.

In order to further improve the uniformity of the evaporation gas escaping from the crucible, as illustrated in FIG. 2 and FIG. 3, the crucible body 10 further includes a cover 30 covering the opening 111 of the first crucible component 11, there are a plurality of evaporation holes 31 arranged on the cover 30, and the evaporation gas escapes from the crucible through the evaporation holes 31, so that the uniformity thereof can be further improved to thereby improve the uniformity of the film formed from the evaporation gas on the substrate. For example, as illustrated in FIG. 2 and FIG. 3, the evaporation holes 31 are arranged in an array on the cover 30, so that the evaporation holes 31 can be distributed uniformly on the cover 30 to thereby further improve the uniformity of the escaping evaporation gas.

In the crucible according to some embodiments of the disclosure, the crucible body 10 includes four second crucible components 12. When there is a smaller volume of each second crucible component 12, the efficiency of heating the evaporation material therein can be improved, but the capacity of the evaporation material in each second crucible component 12 may be lowered, so in some examples, another number of the second crucible component(s) 12 can be set according to the amount of the evaporation material, and a heating rate as required, and for example, the crucible body 10 can include 1, 2, 3, 5, or 6 second crucible components 12.

When the crucible body 10 includes one second crucible component, there is a smaller volume of the second crucible component, so the problem of heating the evaporation material non-uniformly can also be prevented. Furthermore, the material evaporated in the second crucible component can be scattered sufficiently in the first crucible component with a larger volume to thereby increase the evaporation area of the crucible.

The foregoing disclosure is merely illustrative the exemplary embodiments of the disclosure, but not intended to limit the scope of the disclosure as claimed, and the scope of the disclosure as claimed shall be as defined in the appended claims.

1. A crucible, comprising a crucible body, wherein:
the crucible body comprises a first crucible component and at least one second crucible component, and a volume of each of the at least one second crucible component is smaller than that of the first crucible component; and the first crucible component comprises a first opening and a bottom surface facing the first opening, an end of each of the at least one second crucible component is connected with the bottom surface of the first crucible component, and an internal cavity of each of the at least one second crucible component connects with an internal cavity of the first crucible component.

2. The crucible according to claim 1, wherein the crucible body comprises a plurality of second crucible components.

3. The crucible according to claim 2, wherein each of the at least one second crucible component comprises a second opening, the bottom surface of the first crucible component comprises a plurality of through-holes, and the second opening of each of the at least one second crucible component is connected with one of the plurality of through-holes, so that the internal cavity of each of the at least one second crucible component connects with the internal cavity of the first crucible component.

4. The crucible according to claim 2 or 3, wherein the crucible further comprises a heating device arranged outside of each of the at least one second crucible component.

5. The crucible according to claim 4, wherein the heating device comprises an electric heating sleeve arranged outside of each of the at least one second crucible component.

6. The crucible according to claim 4, wherein the heating device comprises electric heating wires arranged outside of each of the at least one second crucible component.

7. The crucible according to claim 2, wherein the crucible further comprises a refrigeration device arranged outside of each of the at least one second crucible component.

8. The crucible according to claim 7, wherein the refrigeration device comprises a cold medium pipe arranged outside of each of the at least one second crucible component.

9. The crucible according to claim 4, wherein the plurality of second crucible components are spaced apart from each other on the bottom surface, and the heating device is configured to encircle each of the plurality of second crucible components.

10. The crucible according to claim 1, wherein an area of a section of the first crucible component in a direction parallel to the bottom surface increases gradually from the bottom surface of the first crucible component to the first opening.

11. The crucible according to claim 10, wherein the first crucible component is structured as a circular truncated cone, a diameter of an end of the first crucible component where the first opening is located is larger than a diameter of an end of the first crucible component where the bottom surface is located.

12. The crucible according to claim 1, wherein the crucible body further comprises a cover covering the first opening of the first crucible component, and there are a plurality of evaporation holes arranged on the cover.

13. The crucible according to claim 12, wherein the plurality of evaporation holes are arranged in an array on the cover.
